(19) United States
(12) Patent Application Publication
(10) Pub. No.: US 2026/0304915 A1
(43) Pub. Date: Oct. 1, 2026

(54) SEMICONDUCTOR DEVICE AND POWER CONVERSION APPARATUS

(71) Applicant: Mitsubishi Electric Corporation, Tokyo (JP)

(72) Inventors: Akifumi IIJIMA, Tokyo (JP); Yuichi NAGAHISA, Tokyo (JP); Kotaro KAWAHARA, Tokyo (JP); Shiro HINO, Tokyo (JP)

(73) Assignee: Mitsubishi Electric Corporation, Tokyo (JP)

(21) Appl. No.: 18/992,301

(22) PCT Filed: Jul. 13, 2022
(86) PCT No.: PCT/JP2022/027513

§ 371 Date: Jan. 8, 2025

(51) Int. Cl. H10D 84/00; H02P 27/08; H10D 62/10; H10D 62/832

(52) U.S. Cl. CPC H10D 84/146; H10D 62/127; H10D 62/8325; H02P 27/08

(57) ABSTRACT

A maximum unipolar current density is increased while electrical field on a body diode in an OFF state of a transistor is reduced. A semiconductor device includes a first separation region and a second separation region. The first separation region extends in a first direction and a second direction in a plan view, the first separation region includes at least one first folding region folded back in the second direction, the second separation region extends in at least the first direction in a plan view, and a width of the second separation region in the second direction is equal to or larger than a width of the first separation region in the first direction or the second direction.

### TECHNICAL FIELD

A technique disclosed in the specification of the present application relates to a semiconductor device.

### BACKGROUND ART

A vertical metal-oxide-semiconductor field-effect transistor, that is a MOSFET, in which silicon carbide is used includes a built-in unipolar diode as a reflux diode in some cases.

For example, proposed in Patent Document 1 is a method of including a Schottky barrier diode, that is an SBD, as a unipolar diode in a unit cell of a MOSFET, and using the SBD.

Such a unipolar transistor including a built-in unipolar diode, that is a diode having electrical conduction in only a large number of carriers in an active region is designed so that diffusion potential of the unipolar diode, that is voltage at which a conduction operation is started is lower than voltage at which a conduction operation of a PN junction in a MOS structure (referred to as a body diode in some cases hereinafter) is started, thus forward direction current and defect extension in the body diode can be suppressed.

### PRIOR ART DOCUMENTS

### Patent Document(s)

Patent Document 1: Japanese Patent Application Laid-Open No. 2018-049951

### SUMMARY

### Problem to be Solved by the Invention

In the MOSFET including the built-in SBD, when current having a specific current density flows in the SBD, electrical conduction of the body diode is started. This specific current density is defined as a maximum unipolar current density.

When a width or a length, that is an area, of the SBD is designed to be large, the maximum unipolar current density increases and the current flowing in the body diode can be suppressed. In the meanwhile, electrical field is easily concentrated in the PN diode formed around the SBD when in an OFF state of the transistor, and leakage current flows and heat is generated, thus an element or a circuit is broken in some cases.

For a reason described above, there is a circumstance that the area of the SBD is preferably designed to be large to increase the maximum unipolar current density and in contrast, a circumstance that the area of the SBD is preferably designed to be small to prevent breakdown of the element in the OFF state of the transistor.

A technique disclosed in the specification of the present application is has been made to solve problems as described above, and it is a technique for increasing a maximum unipolar current density while electrical field on a body diode is reduced in an OFF state of a transistor.

### Means to Solve the Problem

A semiconductor device according to a first aspect of a technique disclosed in the specification of the present application includes: a drift layer of a first conductivity type provided to an upper surface of a semiconductor substrate of a first conductivity type; a plurality of well regions of a second conductivity type provided separately from each other on a surface layer of the drift layer; a source region of a first conductivity type provided to a surface layer of at least one of the well regions; a first separation region of a first conductivity type as a region between the plurality of well regions on the surface layer of the drift layer; a second separation region of a first conductivity type as a region, different from the first separation region, between the plurality of well regions on the surface layer of the drift layer; a gate insulating film provided to have contact with at least one of the well regions sandwiched between the source region and the drift layer; a gate electrode provided to have contact with the gate insulating film; a Schottky electrode provided to an upper surface of the first separation region to have a Schottky junction with the first separation region; an ohmic electrode provided to an upper surface of the source region; and a source electrode provided to have contact with the Schottky electrode and the ohmic electrode, wherein the first separation region extends in a first direction and a second direction as a direction different from the first direction in a plan view, the first separation region includes at least one first folding region folded back in the second direction, the second separation region extends in at least the first direction in a plan view, and a width of the second separation region in the second direction is equal to or larger than a width of the first separation region in the first direction or the second direction.

### Effects of the Invention

According to at least the first aspect of the technique disclosed in the specification of the present application, the first folding region is provided to the first separation region, thus the maximum unipolar current density can be increased. In the meanwhile, the width of the first separation region is smaller than that of the second separation region, thus the electrical field on the PN joint part formed by the first separation region and the well region can be reduced.

These and other objects, features, aspects and advantages relating to the technique disclosed in the specification of the present application will become more apparent from the following detailed description of the present disclosure when taken in conjunction with the accompanying diagrams.

### BRIEF DESCRIPTION OF DRAWINGS

FIG. 1 A plan view of a MOSFET with a built-in SBD as a semiconductor device according to an embodiment.

FIG. 2 A schematic cross-sectional view along a cross section A-A′ in FIG. 1.

FIG. 3 A schematic view illustrating a structure of the plan view in FIG. 1 repetitively and continuously disposed in a direction X and a direction Y.

FIG. 4 A plan view of a terminal part of an active region in the MOSFET with the built-in Schottky diode (SBD) as the semiconductor device according to the embodiment.

FIG. 5 A plan view of a modification example of the MOSFET with the built-in SBD as the semiconductor device according to the embodiment.

FIG. 6 A plan view of a modification example of the MOSFET with the built-in SBD as the semiconductor device according to the embodiment.

FIG. 7 A plan view of the MOSFET with the built-in Schottky diode (SBD) as the semiconductor device according to the embodiment.

FIG. 8 A plan view of the MOSFET with the built-in Schottky diode (SBD) as the semiconductor device according to the embodiment.

FIG. 9 A plan view of the MOSFET with the built-in Schottky diode (SBD) as the semiconductor device according to the present embodiment.

FIG. 10 A schematic view illustrating an example of an arrangement of a cell in a lattice type.

FIG. 11 A block diagram illustrating a configuration of a power conversion system to which a power conversion apparatus according to the embodiment is applied.

FIG. 12 A plan view illustrating an example of a configuration of an active region of the MOSFET with the built-in SBD as the semiconductor device according to the embodiment.

FIG. 13 A schematic cross-sectional view along a cross section A-A′ in FIG. 12.

### DESCRIPTION OF EMBODIMENT(S)

An embodiment is described hereinafter with reference to the accompanying diagrams. Detailed features are also described for explaining a technique in the embodiment hereinafter, however, they are only an exemplification, thus are not always necessary to be able to implement the embodiment.

The diagrams are schematically illustrated, thus omission or simplification of the configuration is performed on the diagrams for explanatory convenience. A mutual relationship of sizes and positions of configurations illustrated in the different diagram is not necessarily accurately illustrated, but can be appropriately changed. A hatching May be drawn in a plane view, for example, as well as a cross-sectional view to easily understand contents of the embodiment.

In the description hereinafter, the same reference numerals are assigned to the similar constituent elements in the illustration, and the same applies to names and functions thereof. Accordingly, the detailed description on them may be omitted to avoid a repetition in some cases.

In the description in the specification of the present application, when there is a description of “comprising”, “including”, or “having” a certain constituent element, such a description does not indicate an exclusive expression excluding the other constituent element unless otherwise noted.

In the description in the specification of the present application, even when ordinal numbers such as “first” or “second” are stated, the terms are used to facilitate understanding of embodiments, and therefore, the embodiments are not limited to an order which may be caused by the ordinal numbers.

In the following description in the specification of the present application, even when terms indicating a specific position or direction such as “upper”, “lower”, “left”, “right”, “side”, “bottom”, “front” or “rear” are stated, the terms are used to facilitate understanding of embodiments for convenience, and therefore, irrelevant to positions or directions in practical implementation of the embodiment.

Further, when “an upper surface of . . . ” or “a lower surface of . . . ” is described in the description in the specification of the present application, it also includes a state where the other constituent element is formed on an upper surface or a lower surface of a target constituent element in addition to the upper surface or the lower surface of the target constituent element. That is to say, when there is a description of “B provided on an upper surface of A”, for example, an intervention of the other constituent element “C” between A and B is not hindered.

### First Embodiment

A semiconductor device relating to the present embodiment is described hereinafter.

In the present specification, a first conductivity type is an n type and a second conductivity type is a p type, however, the first conductivity type may be a p type, and the second conductivity type may be an n type. An n type indicates that the n″ type has a lower impurity concentration than the n type, and an n+ type indicates that the n+ type has a higher impurity concentration than the n type. Similarly, a p″ type indicates that the p type has a lower impurity concentration than the p type, and an p+ type indicates that the p+ type has a higher impurity concentration than the p type.

### <Configuration of Semiconductor Device>

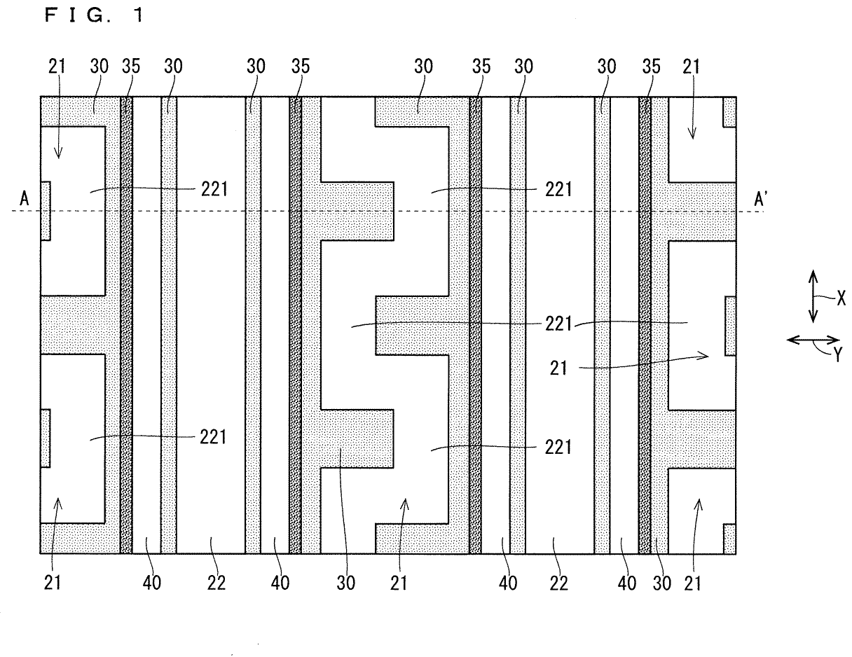

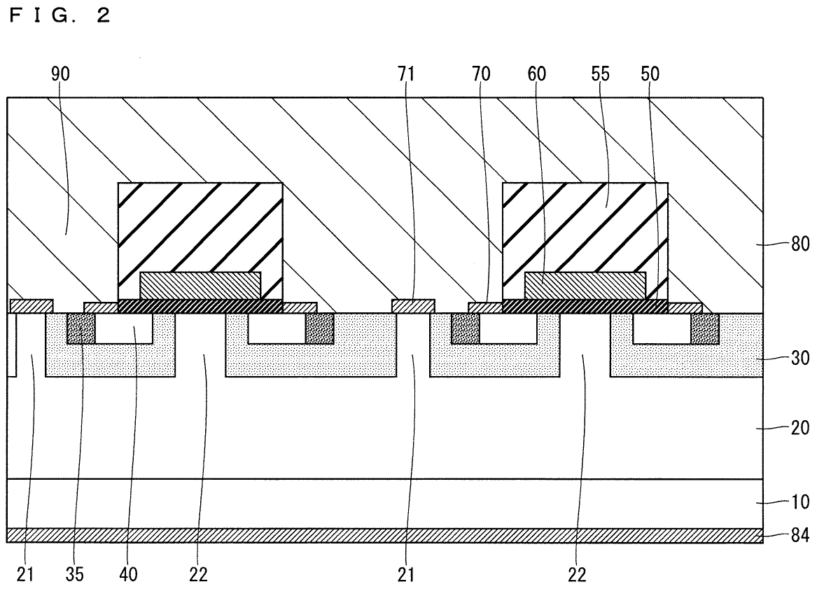

FIG. 1 is a plan view of a MOSFET with a built-in SBD as a semiconductor device according to the present embodiment. The plan view is a diagram of a semiconductor substrate seen from an upper side in a plan view while a source electrode, a gate wiring layer, or an insulating film, for example, are omitted. FIG. 2 is a schematic cross-sectional view along a cross section A-A′ in FIG. 1.

In FIG. 1, provided is a separation region 21 extending in a direction X and a direction Y and including a folding region 221 folded back in the direction Y. The plurality of folding regions 221 are provided in FIG. 1, however, a case where one folding region 221 is provided is also applicable.

In FIG. 2, an n-type drift layer 20 is formed on an upper surface of an n-type semiconductor substrate 10 having low resistance. A plurality of p-type well regions 30 are provided on a surface layer part of the drift layer 20.

An n-type source region 40 is formed in a position closer to an inner side by a predetermined interval from an outer periphery of the well region 30 in a surface layer part of each well region 30.

A p-type contact region 35 having low resistance is formed on a lateral side of the source region 40 in the surface layer part of each well region 30. An n-type separation region 21 is formed between the well regions 30 formed separately from each other in the surface layer part of the drift layer 20.

An n-type impurity concentration of the separation region 21 may be equal to or higher or lower than that of the drift layer 20.

A Schottky electrode 71 Schottky-connected to the separation region 21 is formed on an upper surface of the separation region 21. Herein, it is preferable that the Schottky electrode 71 is formed to cover at least the separation region 21 in a plan view, that is to say, an area of the Schottky electrode 71 is larger than that of the separation region 21.

A region, which is different from the separation region 21, between the well regions 30 formed separately from each other in the surface layer part of the drift layer 20 is an n-type separation region 22. The separation region 22 has the same width as or a larger width than a width of the separation region 21. In other words, the separation region 21 has the same width as or a smaller width than a width of the separation region 22.

An n-type impurity concentration of the separation region 22 may be equal to or higher or lower than that of the drift layer 20.

A gate insulating film 50 is formed on an upper surface of the well region 30, an upper surface of the separation region 22 between the well regions 30, and an upper surface of the source region 40 in each well region 30. The gate insulating film 50 is provided to have contact with the well region 30 sandwiched between the source region 40 and the drift layer 20.

A gate electrode 60 is formed in a range overlapped with the source region 40 and the well region 30 in a plan view in an upper surface of the gate insulating film 50. The surface layer part of the well region 30 facing the gate electrode 60 with the gate insulating film 50 therebetween in a lower side of a position where the gate electrode 60 is formed is referred to as a channel region.

An ohmic electrode 70 is formed on a part of the upper surface of the source region 40 and a part of an upper surface of the contact region 35. Then, a source electrode 80 is formed to cover the ohmic electrode 70 and the Schottky electrode 71.

The source region 40 can easily supply and receive electrons via the ohmic electrode 70. The well region 30 can easily supply and receive positive holes via the contact region 35 having low resistance and the ohmic electrode 70.

However, the ohmic electrode 70 does not have contact with the separation region 21. According to such a configuration, ohmic contact does not function as a bypass of the Schottky junction formed between the separation region 21 and the source electrode 80. Specifically, the separation region 21 and the ohmic electrode 70 are electrically separated from each other by the contact region 35 and the well region 30.

An interlayer insulating film 55 is formed to cover the gate electrode 60. A source electrode 80 has contact with an upper surface of the ohmic electrode 70, an upper surface of the Schottky electrode 71, and an upper surface of the contact region 35 via a contact hole 90 formed to pass through the interlayer insulating film 55 and the gate insulating film 50.

In the meanwhile, a drain electrode 84 is formed on a lower surface of the semiconductor substrate 10.

As illustrated in FIG. 1, the well region 30, the contact region 35, and the separation region 22 extend along the direction X to be formed into a stripe shape. The gate electrode 60 in FIG. 2 is also formed to extend along the direction X.

The separation region 21 extends along the direction X and the direction Y which is the direction different from the direction X, and is disposed to be repetitively folded back between the well regions 30 (the folding is generated in the folding region 221). This configuration is defined as an accordion-like (zigzag) arrangement.

When the separation region 21 is disposed to have the accordion-like shape, the width of the separation region 21 is set to be equal to or smaller than that of the separation region 22.

In FIG. 1, the direction X is the direction parallel to a direction in which the well region 30, the contact region 35, and the separation region 22 extend, and the direction Y is the direction perpendicular to the direction X.

### <Operation of Semiconductor Device>

Described next is an operation of a MOSFET with a built-in SBD as a semiconductor device according to the present embodiment. Described hereinafter is an example of a silicon carbide semiconductor device in which a semiconductor material is a 4H-type silicon carbide. In this case, diffusion potential of a PN junction is approximately 2V.

A case of a reflux operation is described firstly.

In the reflux operation, current tends to flow from the source electrode 80 to the drain electrode 84. Particularly, when OFF voltage is applied to the gate electrode 60, there is no current route passing a channel.

At this time, the SBD turned on with lower voltage than the body diode made up of the well region 30 and the drift layer 20 is formed between the separation region 21 and the Schottky electrode 71, thus when a current density is low, the reflux current wholly flows to the SBD, and does not flow to the body diode.

However, when the current density gets high, voltage larger than approximately 2V occurs as voltage depression occurring in a Schottky interface and the separation region 21 and is applied to the PN junction parallelly arranged, and current conduction in the body diode is started.

In order to increase the current density at this time, that is to say, the maximum unipolar current density, it is effective to increase an n-type concentration of the separation region 21 or increase the width of the separation region 21 to reduce resistance of the separation region 21. However, in any method, electrical field intensity applied to the Schottky interface or the PN joint part increases in an OFF state of a transistor.

Herein, when the separation region 21 is meanderingly disposed as the present embodiment, an amount of electrons flowing via the SBD can be increased without increasing the n-type concentration and the width of the separation region 21, and the maximum unipolar current density can be increased.

As a cycle of the meandering of the separation region 21 gets shorter, the amount of electrons flowing via the SBD can be increased, thus the maximum unipolar current density can be further increased.

A case where the transistor is an OFF state is described next.

When the transistor is in the OFF state, electrical field is easily concentrated in the PN joint part formed by the separation region 21 and the well region 30 and the PN joint part formed by the separation region 22 and the well region 30.

Reduction of the width of the separation region 21 and the width of the separation region 22 is considered as a method of reducing the electrical field concentration in the PN joint part formed by the separation region 21 and the well region 30 and the PN joint part formed by the separation region 22 and the well region 30. When the width of the separation region 21 and the width of the separation region 22 are reduced, potential variation in the separation region 21 and the separation region 22 is reduced in the OFF state of the transistor. Thus, the electrical field concentration in the PN joint part formed by the separation region 21 and the well region 30 and the PN joint part formed by the separation region 22 and the well region 30 can be reduced.

As illustrated in FIG. 2, the gate insulating film 50 is formed on the upper surface of the separation region 22, and the gate insulating film 50 shares voltage applied to the whole device by applying reverse voltage in the OFF state of the transistor. Accordingly, the electrical field on the PN joint part formed by the separation region 22 and the well region 30 is reduced. Thus, high electrical field is easily concentrated in the PN joint part formed by the separation region 21 and the well region 30 with no layer sharing the electrical field on the upper surface.

Thus, when the width of the separation region 21 is smaller than that of the separation region 22, the electrical field on the PN joint part formed by the separation region 21 and the well region 30 can be reduced. Thus, breakdown of an element in the OFF state of the transistor can be suppressed.

For the above reason, when the width of the separation region 21 is set to be equal to or smaller than that of the separation region 22 when the separation region 21 is meanderingly disposed, the electrical field concentration in the body diode formed by the separation region 21 and the well region 30 in the OFF state of the transistor is suppressed, and breakdown of the element can be prevented.

As described above, according to the semiconductor device of the present embodiment, the operation of the body diode in the reflux operation is suppressed, thus the maximum unipolar current density can be increased, and breakdown of the element in the OFF state of the transistor can be suppressed, and a tradeoff relationship therebetween can be improved.

### <Method of Manufacturing Semiconductor Device>

Described next is a method of manufacturing a MOSFET with a built-in SBD as a semiconductor device according to the present embodiment. Described hereinafter is an example of a silicon carbide semiconductor device in which a semiconductor material is a 4H-type silicon carbide.

The drift layer 20 made of n-type silicon carbide is epitaxially grown on upper surface of the semiconductor substrate 10 having 4H polytype and made of an n-type low-resistive silicon carbide with a first main surface having a plane orientation being a (0001) plane by a chemical vapor deposition (CVD) method to have a thickness of 5 μm to 50 μm at an impurity concentration of 1×10¹⁵ to 1×10¹⁷ cm⁻³, for example.

Subsequently, an implantation mask is formed by photoresist, for example, in a predetermined region in the upper surface of the drift layer 20, and aluminum (Al) as a p-type impurity is ion-implanted. At this time, a depth of the ion implantation of Al is set within a range from 0.5 μm to 3 μm so as not to exceed the thickness of the drift layer 20. An impurity concentration of ion-implanted Al has a maximum value at a depth away from the upper surface of the drift layer 20, and is set within a range from 1×10¹⁷ cm⁻³ to 1×10¹⁹ cm⁻³ to be higher than that of the drift layer 20. In contrast, the impurity concentration of the implanted Al is low in the upper surface of the drift layer 20, and is within a range from 1×10¹⁵ cm⁻³ to 1×10¹⁸ cm⁻³. Then, the implantation mask is removed. The region where Al is ion-implanted in the present process serves as the well region 30.

Next, an implantation mask is formed by photoresist on the upper surface of the drift layer 20, and Al having the p-type impurity concentration is ion-implanted. At this time, a depth of the ion implantation of Al is set within a range from 0.5 μm to 3 μm so as not to exceed the thickness of the drift layer 20. The implantation depth of ion implantation of Al is smaller than the well region 30 so that implantation defect having a high concentration remains inside the well region 30. An impurity concentration of ion-implanted Al is within a range from 1×10¹⁹ cm⁻³ to 1×10²¹ cm⁻³ to be higher than that of the drift layer 20 and lower than that of the well region 30. Then, the implantation mask is removed. The region where Al is ion-implanted in the present process serves as the contact region 35.

Next, an implantation mask is formed by photoresist, for example, so that a predetermined position inside the well region 30 in the upper surface of the drift layer 20 is opened in a plan view. Then, nitrogen (N) as an n-type impurity is ion-implanted. An ion-implantation depth of N is smaller than the thickness of the well region 30. The impurity concentration of the ion-implanted N is set within a range from 1×10¹⁸ cm⁻³ to 1×10²¹ cm⁻³ to be higher than a p-type impurity concentration of the well region 30. The impurity concentration of N is preferably larger than 1×10¹⁹ cm⁻³ to reduce sheet resistance or contact resistance with the ohmic electrode 70. A region showing the n-type conductivity in the region where N is implanted in the present process serves as the source region 40.

Next, anneal processing is performed at a temperature of 1300 to 1900° C. for thirty seconds to one hour, for example, in an inactive gas atmosphere such as argon (Ar) gas in a thermal processing apparatus (not shown herein). The ion-implanted N and Al are electrical activated by this anneal processing.

Subsequently, a field insulating film (not shown herein) made of silicon oxide with a film thickness of 0.5 μm to 2 μm, larger than that of the gate oxide film, is formed on the upper surface of the drift layer 20 in a region other than the active region (that is to say, a region substantially corresponding to the region where the well region 30 is formed) using a CVD method or a photolithography technique, for example.

Next, the upper surface of the drift layer 20 which is not covered by the field insulating film is thermally oxidized to form a silicon oxide film as the gate insulating film 50 having a desired thickness. Substantially, a polycrystal silicon film having conductivity is formed by a decompression CVD method on an upper surface of the gate insulating film 50 or an upper surface of the field insulating film, and furthermore, the polycrystal silicon film is patterned to form the gate electrode 60.

Next, the interlayer insulating film 55 made of silicon oxide is formed by a decompression CVD method. Formed subsequently is the contact hole 90 passing through the interlayer insulating film 55 and the gate insulating film 50 to reach the contact region 35 and the source region 40 in the active region.

Next, after a metal film containing Ni as a main component is formed by a sputtering method, for example, a thermal treatment is performed at a temperature of 600° C. to 1100° C., and the metal film containing Ni as the main component and a silicon carbide layer in the contact hole 90 are reacted to form silicide between the silicon carbide layer and the metal layer.

Subsequently, the remaining metal film other than silicide formed in the above reaction is removed by wet etching. The ohmic electrode 70 is thereby formed.

Subsequently, a metal film containing Ni as a main component is formed on the lower surface (second main surface) of the semiconductor substrate 10, and a thermal treatment is further performed to form a back surface ohmic electrode (not shown herein) on a side of the lower surface of the semiconductor substrate 10.

Next, the interlayer insulating film 55 and the gate insulating film 50 on the upper surface of the separation region 21 are removed using a patterning by photoresist, for example. Applied as the method of removing the films is wet etching which does not cause damage to a surface of the silicon carbide layer as the Schottky interface. After the wet etching, the photoresist is removed when the photoresist is used.

Subsequently, a metal film as a Schottky electrode is deposited by a sputtering method, for example, and the Schottky electrode 71 is formed on the upper surface of the separation region 21 in the contact hole 90 using a patterning by photoresist, for example. For example, Ti or Mo may be applicable as a material of the Schottky electrode 71.

Next, a wiring metal such as Al is formed on the upper surface of the drift layer 20 in which the Schottky electrode 71 described above is formed by a sputtering method of a vapor deposition method. Then, the ohmic electrode 70 on a source side, the source electrode 80 having contact with the Schottky electrode 71, and a gate pad (not shown herein) and a gate wiring (not shown herein) having contact with the gate electrode 60 are formed by processing the wiring metal into a predetermined shape by a photolithography technique.

Furthermore, when the drain electrode 84 as a metal film is formed on a lower surface of the back surface ohmic electrode (not shown herein) formed on the lower surface of the semiconductor substrate 10, the semiconductor device illustrated in FIG. 1 and FIG. 2 is completed.

The example of performing each ion implantation in a predetermined order is described in the present embodiment, however, the order of the ion implantation may be appropriately changed. An order of forming the back surface ohmic electrode on the lower surface of the semiconductor substrate 10 and the ohmic electrode 70 and the Schottky electrode 71 on the upper surface of the semiconductor substrate 10 may be appropriately changed.

Described in the present embodiment is an example of forming the Schottky electrode 71 only on the upper surface of the separation region 21 and the upper surface of the well region 30, however, the Schottky electrode 71 may be formed on the upper surface of the ohmic electrode 70 or the upper surface of the interlayer insulating film 55.

It is assumed in the present embodiment that the channel or the Schottky electrode 71 is a planar type formed in parallel to the main surface of the semiconductor substrate 10, however, it is also applicable that the channel or the Schottky electrode 71 is a trench type formed obliquely or perpendicular to the main surface of the semiconductor substrate 10. That is to say, also applicable is a trench gate in which a trench passing through the well region 30 to reach the drift layer 20 is provided and the gate insulating film 50 and the gate electrode 60 are formed on an inner side of the trench.

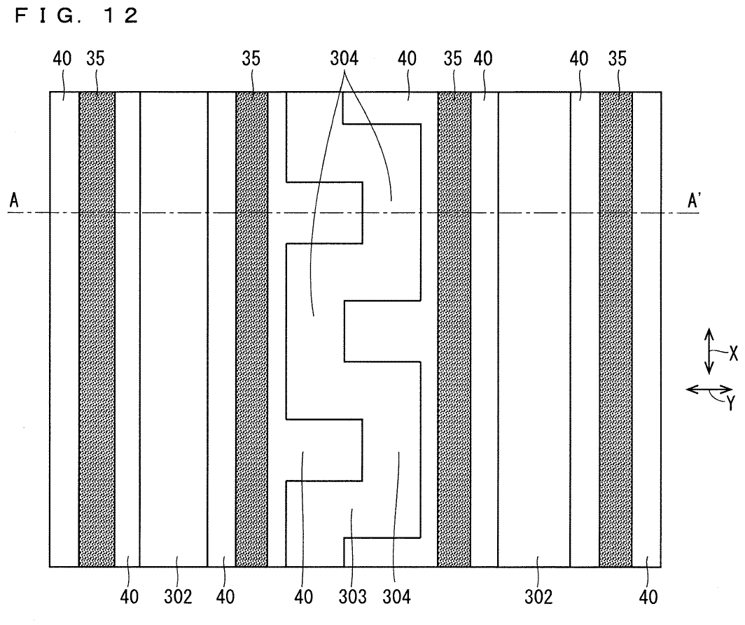

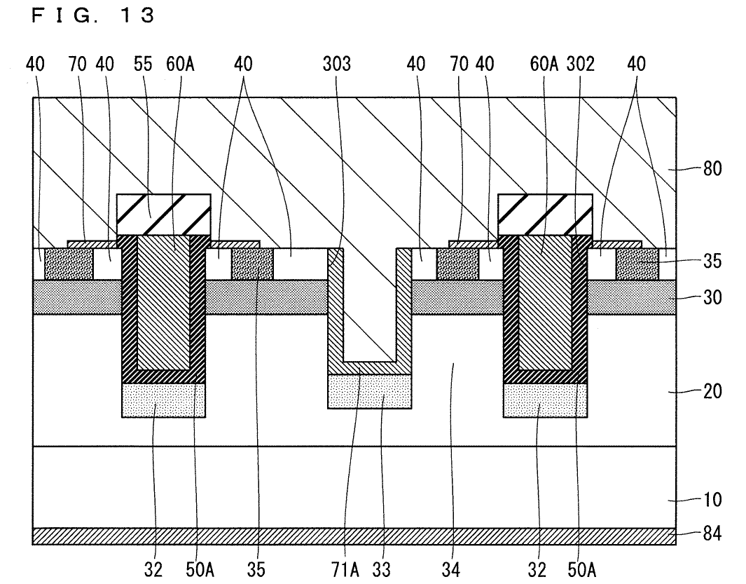

FIG. 12 is a plan view illustrating an example of a configuration of an active region of an SiC-MOSFET with a built-in trench-type SBD as the semiconductor device according to the present embodiment. FIG. 13 is a schematic cross-sectional view along a cross section A-A′ in FIG. 12.

In FIG. 12 and FIG. 13, the drift layer 20 made of n-type silicon carbide is formed on the upper surface of the semiconductor substrate 10 made of n-type silicon carbide having low resistance. The well region 30 made of p-type silicon carbide is formed on the surface layer part of the drift layer 20.

The source region 40 made of n-type silicon carbide is formed on the surface layer part of a part of the well region 30. A p-type contact region 35 having low resistance is formed in a region adjacent to the source region 40 in the surface layer part of the well region 30.

Formed in the active region is a gate trench 302 passing through the source region 40 and the well region 30 to reach the drift layer 20.

A Schottky trench 303 passing through the source region 40 and the well region 30 to reach the drift layer 20 is formed in a position different from the position where the gate trench 302 is formed.

The gate trench 302 and the Schottky trench 303 are alternately disposed to extend in parallel to each other. The gate trench 302 and the Schottky trench 303 may be formed to have the same width, or widths thereof may be different from each other.

A gate electrode 60A is formed in the gate trench 302 to be surrounded by a gate insulating film 50A made of silicon carbide. The gate electrode 60A is made of polycrystal silicon having a high impurity concentration and low resistance. The interlayer insulating film 55 made of silicon oxide is formed on an upper surface of the gate electrode 60A.

The source electrode 80 is formed in the Schottky trench 303 to be surrounded by a Schottky electrode 71A. The Schottky electrode 71A is formed to have contact with the drift layer 20, and is Schottky-connected to the drift layer 20. A p-type protection region 32 is formed in the drift layer 20 having contact with a bottom surface of the gate trench 302. A p-type protection region 33 is formed in the drift layer 20 having contact with a bottom surface of the Schottky trench 303. A depth of the protection region 32 may be the same as or different from that of the protection region 33. An impurity concentration of the protection region 32 may be the same as or different from that of the protection region 33.

The ohmic electrode 70 is formed on a part of the upper surface of the source region 40 and a part of the upper surface of the contact region 35. Then, the source electrode 80 is formed to cover the ohmic electrode 70 and the Schottky electrode 71A.

In the meanwhile, the drain electrode 84 is formed on the lower surface of the semiconductor substrate 10.

Described hereinafter is an operation of the SiC-MOSFET with the built-in trench-type SBD as the semiconductor device according to the present embodiment.

A case of a reflux operation is described firstly.

In the manner similar to the case of the SiC-MOSFET with the built-in planar-type SBD, when the current density is low, the reflux current wholly flows to the SBD, and does not flow to the body current in the reflux operation. In the meanwhile, when the current density is high, voltage larger than approximately 2V occurs as voltage depression occurring in Schottky interface and the separation region 34 as a region sandwiched by the Schottky trench 303 and the gate trench 302 and is applied to the PN junction parallelly arranged, and current conduction in the body diode is started.

In order to increase the current density in this case, that is to say, the maximum unipolar current density, it is effective to increase an n-type concentration of the separation region 34 or increase a depth of the separation region 34 (that is to say, increase a depth of the gate trench 302 and the Schottky trench 303) to reduce resistance of the separation region 34.

However, in any method, electrical field intensity applied to the Schottky interface or the PN joint part increases in the OFF state of the transistor.

Herein, when the Schottky trench 303 is meanderingly disposed as with the present embodiment, the separation region 34 is also meanderingly disposed in accordance with the meandering of the Schottky trench 303. Herein, a region where the Schottky trench 303 meandering to have a zigzag shape is folded back in the direction Y is a folding region 304. In FIG. 12, the plurality of folding regions 304 are provided at a regular interval, however, the interval at which the folding region 304 is provided may not be constant.

In such a case, the amount of electrons flowing via the SBD can be increased without increasing the n-type concentration and the depth of the separation region 34 (that is to say, without increasing the depths of the gate trench 302 and the Schottky trench 303), and the maximum unipolar current density can be increased.

A case where the transistor is in the OFF state is described next.

When the transistor is in the OFF state, the electrical field is easily concentrated in the PN joint part formed by the protection region 32 and the drift layer 20 and the PN joint part formed by the protection region 33 and the drift layer 20.

Reduction of the depth of the separation region 34 (that is to say, reduction of the depth of the gate trench 302 and the Schottky trench 303) is considered as a method of reducing the electrical field concentration in the PN joint part formed by the separation region 32 and the drift layer 20 and the PN joint part formed by the protection region 33 and the drift region 20. When the depths of the gate trench 302 and the Schottky trench 303 are reduced, potential variation in the separation region 34 in the OFF state of the transistor decreases. Thus, the electrical field concentration in the PN joint part formed by the protection region 32 and the drift layer 20 and the PN joint part formed by the protection region 33 and the drift layer 20 can be reduced.

As illustrated in FIG. 13, the gate insulating film 50A is formed on an upper part of the protection region 32, and the gate insulating film 50A shares voltage applied to the whole device by applying reverse voltage in the OFF state of the transistor. Accordingly, the electrical field on the PN joint part formed by the protection region 32 and the drift layer 20 is reduced. Thus, high electrical field is easily concentrated in the PN joint part formed by the protection region 33 and the drift layer 20 with no layer sharing the electrical field on the upper part.

Thus, when the depth of the Schottky trench 303 is equal to or smaller than that of the gate trench 302, the electrical field on the PN joint part formed by the protection region 33 and the drift layer 20 can be reduced. Thus, breakdown of an element in the OFF state of the transistor can be suppressed.

In addition, when the depth of the Schottky trench 303 is equal to or smaller than that of the gate trench 302, the electrical field on the Schottky electrode 71 can also be reduced. Thus, leakage current in the case of the OFF state of the transistor can be suppressed.

For the above reason, when the depth of the Schottky trench 303 is set to be equal to or smaller than that of the gate trench 302 when the Schottky trench 303 is meanderingly disposed, the electrical field concentration in the body diode formed by the protection region 33 and the drift layer 20 in the OFF state of the transistor is suppressed, and breakdown of the element can be prevented. In addition, the electrical field on the Schottky electrode 71 can be reduced, and the leakage current can be suppressed.

As described above, according to the semiconductor device of the present embodiment, the operation of the body diode in the reflux operation is suppressed, thus the maximum unipolar current density can be increased, and breakdown of the element in the OFF state of the transistor can be suppressed. Furthermore, the leakage current can also be reduced, and the tradeoff relationship therebetween can be improved.

When Al ions are implanted to form the well region 30, the ion implantation is performed while the separation region 21 is covered by a photoresist, for example, and at this time, the photoresist may fall in some cases. As the width of the separation region 21 gets smaller, a dimension of the photoresist to be used also decreases, thus the photoresist easily falls.

In the meanwhile, in the present embodiment, the separation region 21 is meanderingly disposed, thus the photoresist used in the Al ion implantation is also meanderingly formed. In this case, the photoresist falls more hardly than a case of forming the photoresist in straight, thus occurrence of pattern defect can be suppressed.

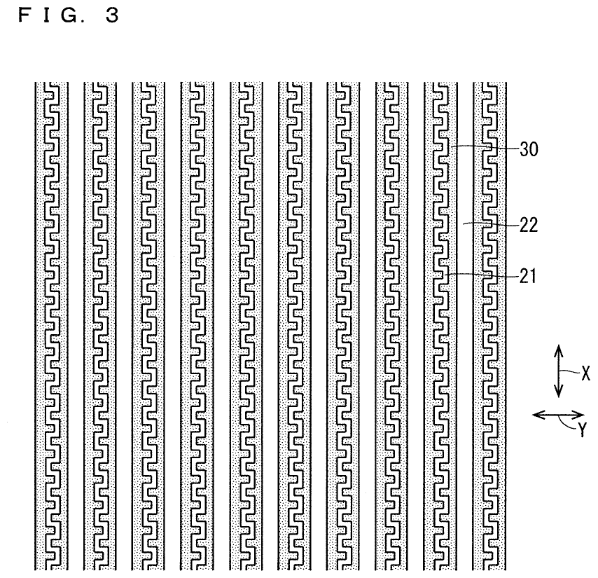

FIG. 3 is a schematic view illustrating a structure of the plan view in FIG. 1 repetitively and continuously disposed in the direction X and the direction Y. FIG. 3 illustrates only the separation region 21, the well region 30, and the separation region 22 for convenience. Assumed mainly hereinafter is the structure of the planar-type SiC-MOSFET with the built-in SBD, however, a trench-type SiC-MOSFET with the built-in SBD illustrated in FIG. 12 and FIG. 13 described above can be appropriately applied alternatively. In such a case, the meandering separation region 21 can be appropriately read as the Schottky trench 303.

In FIG. 3, the p-type well regions 30 substantially corresponding to the MOSFET in a plan view are formed to sandwich the n-type separation region 21 substantially corresponding to the SBD in a plan view in the direction Y. Then, bands of the well regions 30 sandwiching the separation region 21 and extending in the direction X are repetitively disposed in a stripe shape in the direction Y. Such an arrangement is referred to as “stripe type”.

In the above stripe type, when a plane orientation of the upper surface (first main surface) of the semiconductor substrate 10 is a (0001) plane having an OFF angle in a <11-20> direction, the stripe-like well regions 30 extending in the direction X may be formed in parallel to the <11-20> direction (that is to say, an OFF direction), or may also be formed in parallel to a direction perpendicular to the OFF direction.

When the region where the MOSFET with the built-in SBD exemplified in FIG. 3 is formed is referred to as the active region, in a case where a cycle in which the separation region 21 extends in the direction X and the direction Y is constant, that is to say, when a cycle of the meandering is constant, the maximum unipolar current density in the active region in a semiconductor chip becomes uniform, and performance of the element can be increased. However, the cycle of the meandering may be appropriately changed in accordance with a formation position of the active region in the semiconductor chip.

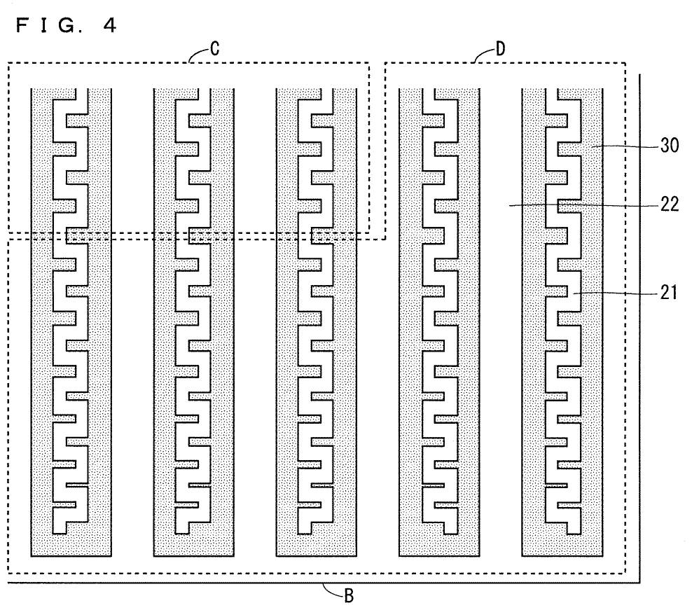

FIG. 4 is a plan view of a terminal part of the active region in the MOSFET with the built-in Schottky diode (SBD) as the semiconductor device according to the present embodiment. FIG. 4 illustrates an active region C in which a cycle of meandering of the separation region 21 is constant, a proximity region D of an active region end in which a cycle of meandering of the separation region 21 is not constant, and a terminal end portion B (active region end) of the active region. The proximity region D of the active region end is disposed to surround the active region C. The terminal end portion B of the active region is disposed to surround the proximity region D of active region end.

A current density of the SBD tends to be small in the terminal end portion B of the active region. Thus, as exemplified in FIG. 4, the cycle of meandering of the separation region 21 is constant in the active region C, and the number of meanderings of the separation region 21 is increased (that is to say, the cycle of meandering is shortened) in the proximity region D of the active region end, thus the current density of the SBD in the proximity region D of the active region end can be increased. Thus, reduction of the maximum unipolar current which may occur in the terminal end portion B of the active region in the reflux operation can be suppressed, and performance of the element can be improved.

FIG. 1 illustrates an example that the separation region 21 includes the folding region 221 having a part extending along the direction X and the part extending along the direction Y perpendicular to the direction X, thereby meandering. However, it is sufficient that the separation region 21 includes a component extending along the direction X and a component extending along the direction Y.

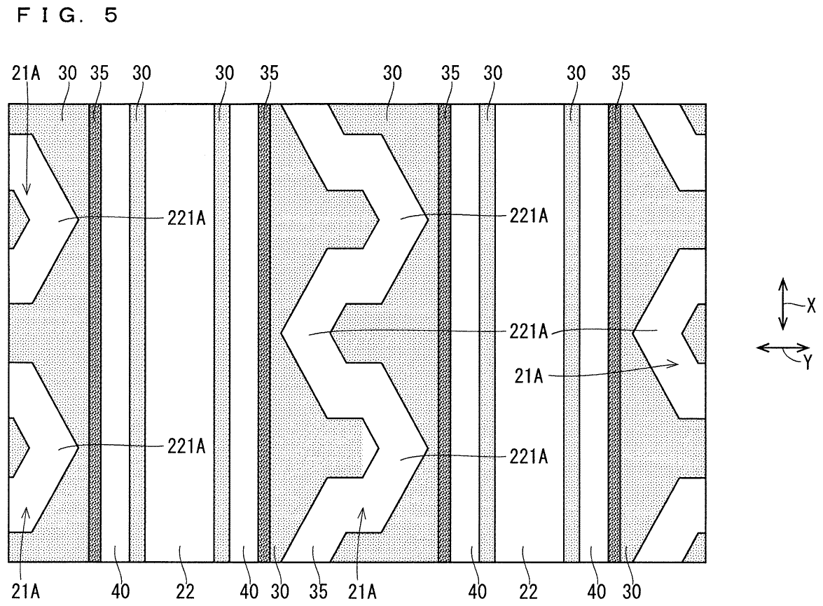

That is to say, as exemplified in FIG. 5, it is applicable that the separation region 21A includes the folding region 221A having a part extending in two directions inclined with respect to the direction X, thereby being disposed to be repetitively bended. There is no limitation on the direction in which the separation region extends, thus the part may extend in three or more directions. FIG. 5 is a plan view of a modification example of the MOSFET with the built-in SBD as the semiconductor device according to the present embodiment.

### Modification Example

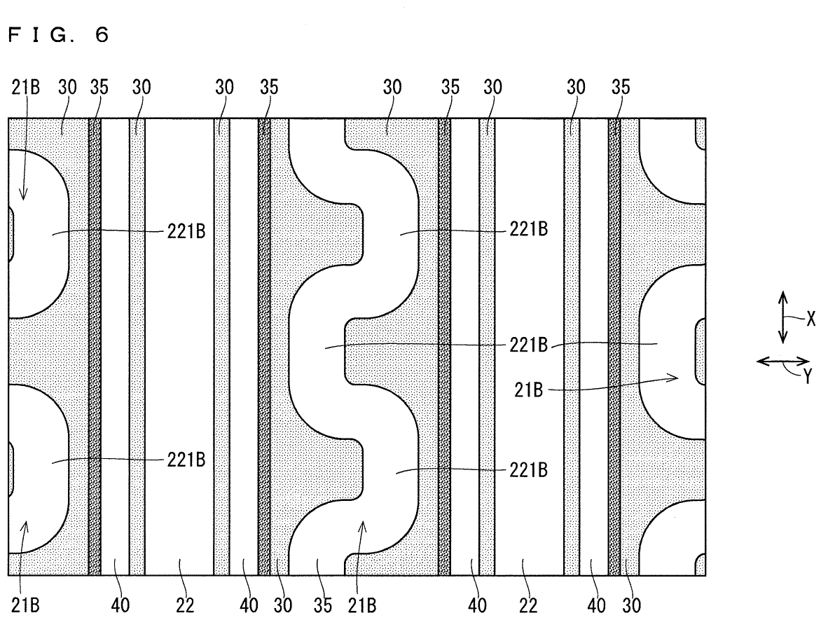

FIG. 6 is a plan view of a modification example of the MOSFET with the built-in SBD as the semiconductor device according to the present embodiment. When the separation region 21B is bended, the separation region 21B may be bended in a curved form in the folding region 221B as exemplified in FIG. 6. When the separation region 21B is bended in the curved form in a plan view, change of the width of the separation region 21B in bending (that is to say, change of the width in the direction Y, the width in the direction inclined in the direction X and the direction Y, and the width in the direction X) decreases. Thus, the electrical field concentration in the PN joint part formed by the separation region 21B and the well region 30 in the OFF state of the transistor is easily reduced.

When the separation region 21B is bended in the curved form, there is no limitation on a curvature thereof, and the width thereof needs to be constant as long as the width is equal to or smaller than that of the separation region 22. When the width of the separation region 21B is constant, local electrical field concentration in the OFF state of the transistor hardly occurs, thus the element is hardly broken.

When the region where the separation region 21B is bended is formed into the curved shape, a corner part becomes a curved part, thus the electrical field concentration in the region is reduced.

### Second Embodiment

A semiconductor device relating to the present embodiment is described. In the description hereinafter, the same reference numerals as those described in the above embodiment will be assigned to the similar constituent elements in the diagrams, and detailed description thereof is appropriately omitted.

### <Configuration of Semiconductor Device>

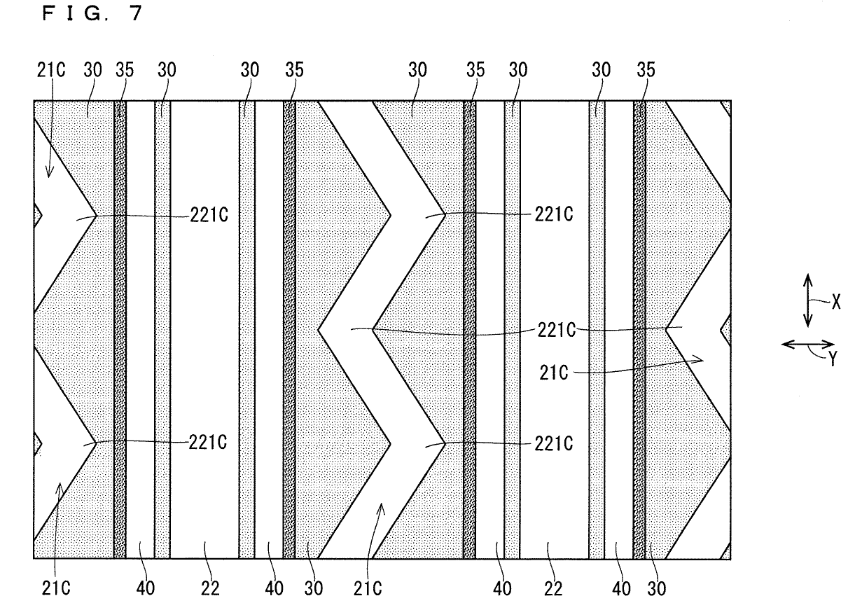

FIG. 7 is a plan view of the MOSFET with the built-in Schottky diode (SBD) as the semiconductor device according to the present embodiment.

A separation region 21C includes a folding region 221C having a part extending in two direction inclined with respect to the direction X (direction inclined with respect to the direction Y), thereby being disposed to be repetitively bended in a zigzag form between the well regions 30. Differing from the separation region 21A, the separation region 21C does not include a part as a component only in the direction Y (that is to say, a part between the folding regions 221A).

A pattern of the separation region 21C in the present embodiment is simple, thus a collapse of the pattern hardly occurs in forming the pattern by a photoresist.

As a cycle of bending the separation region 21C in the zigzag form gets shorter, the area of the SBD increases, thus a power conduction capacity of the SBD increases, and the maximum unipolar current density increases.

The cycle of bending the separation region 21C in the zigzag form or the width of the separation region 21 needs not be constant, but can also be applied to a stripe type or a lattice type (an arrangement in which the separation region 22 is disposed in a lattice form in a plan view).

When the separation region 21C is bended, the separation region 21C may be bended in a curved form. There is also no limitation on the number of bending of the separation region 21C.

### Modification Example

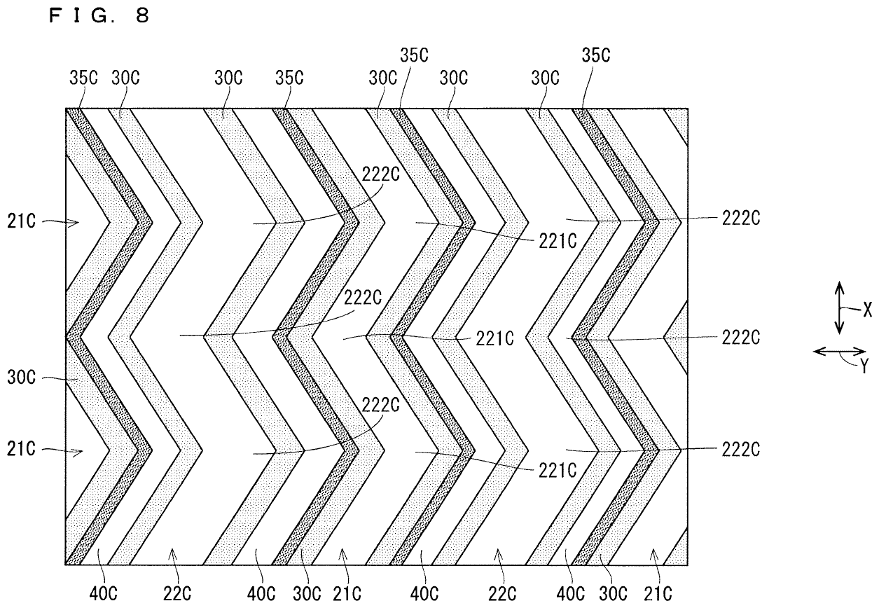

FIG. 8 is a plan view of a modification example of the MOSFET with the built-in Schottky diode (SBD) as the semiconductor device according to the present embodiment.

In FIG. 8, the separation region 22C includes a folding region 222C having a part . . . extending in two directions inclined with respect to the direction X in the same cycle as the cycle of bending the separation region 21C in the zigzag form (that is to say, the cycle of providing the folding region 221C), thereby being disposed to be repetitively bended. Shapes of the well region 30C, the contact region 35C, and the source region 40C in a plan view are also changed in accordance with above configuration.

The separation region 22C is disposed to be bended in the zigzag form so that the cycle of bending the separation region 22C (that is to say, the cycle of providing the folding region 222C) coincides with the cycle of bending the separation region 21C (that is to say, the cycle of providing the folding region 221C), thus the separation region 21C and the separation region 22C extend in parallel to each other in the direction X, and a pitch of cells in the direction Y in FIG. 8 can be reduced. Thus, the semiconductor chip can be downsized.

The cycle or the width of bending the separation region 22C in the zigzag form needs not be constant. When the separation region 21C and the separation region 22C are bended, the separation region 21C and the separation region 22C may be bended in a curved form. There is no limitation on the number of bending of the separation region 21C.

### Third Embodiment

A semiconductor device relating to the present embodiment is described. In the description hereinafter, the same reference numerals as those described in the above embodiment will be assigned to the similar constituent elements in the diagrams, and detailed description thereof is appropriately omitted.

### <Configuration of Semiconductor Device>

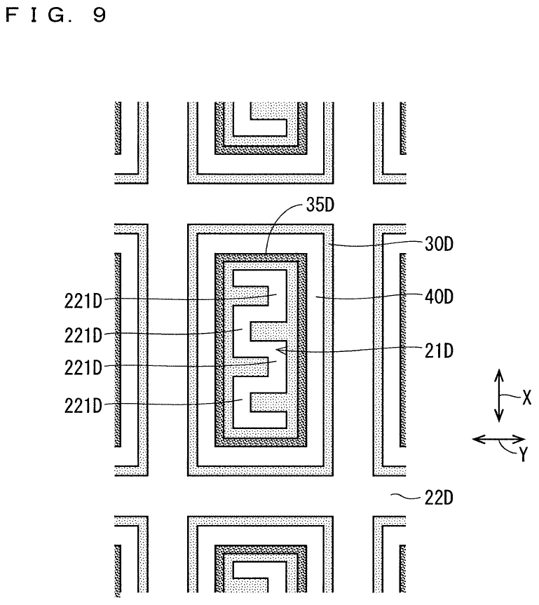

The cell structure is not limited to the stripe type, however, the lattice type, for example, is also applicable. FIG. 9 is a plan view of the MOSFET with the built-in Schottky diode (SBD) as the semiconductor device according to the present embodiment. In the first embodiment and the second embodiment, the separation region 21 disposed to be bended is repetitively provided side by side in one direction (direction Y) in a plan view, however, in the present embodiment, a lattice-like cell including the separation region 21 is repetitively disposed separately from each other in each of the direction X and the direction Y. Such a structure is referred to as “the lattice type”.

In FIG. 9, a separation region 21D including a folding region 221D having a part extending along the direction X and a part extending along the direction Y perpendicular to the direction X, thereby being disposed to be bended is repetitively disposed separately from each other in the direction X and the direction Y. Then, the well region 30D is repetitively disposed separately from each other in the direction X and the direction Y while sandwiching the separation region 21D. Furthermore, the contact region 35D is repetitively disposed separately from each other in the direction X and the direction Y while sandwiching the well region 30D. Furthermore, the source region 40D is repetitively disposed separately from each other in the direction X and the direction Y while sandwiching the contact region 35D. Furthermore, the well region 30D is repetitively disposed separately from each other in the direction X and the direction Y while sandwiching the source region 40D. Furthermore, the separation region 22D is disposed to extend in the direction X and the direction Y while sectioning the well region 30D in the lattice form.

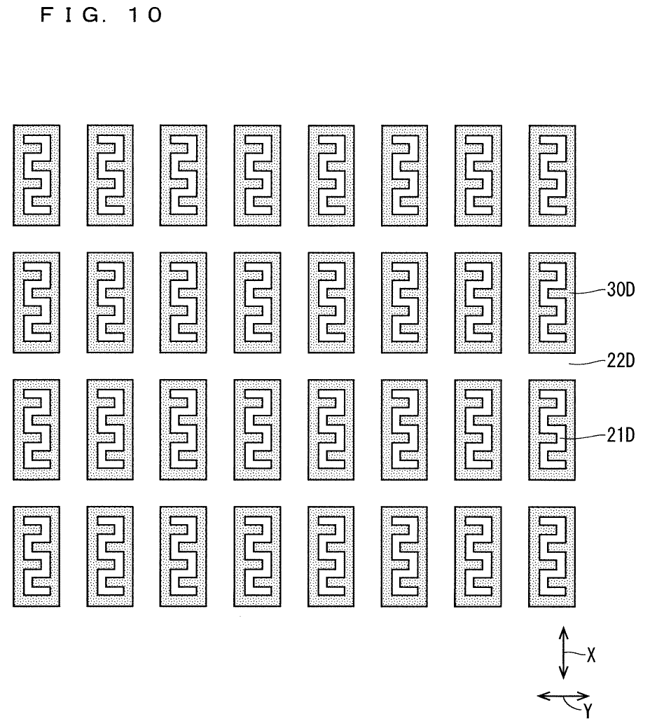

FIG. 10 is a schematic view illustrating an example of an arrangement of a cell in a lattice type. FIG. 10 illustrates only the separation region 21D, the well region 30D, and the separation region 22D.

In the lattice type, a unit cell region made up of the n-type separation region 21D substantially corresponding to the SBD and the p-type well region 30D substantially corresponding to the MOSFET is sectioned by the separation region 22D, and is repetitively disposed in the direction and the direction Y in a plan view.

The separation region 21D is disposed to be repetitively bended as the first embodiment and the second embodiment. Then, the well region 30D is disposed to surround the separation region 21D. There is no limitation on the number of bending of the separation region 21D in the unit cell region, thus may be bended several times. The cycle or the number of bending of the separation region 21D in each unit cell region may be appropriately changed in accordance with the formation position in the semiconductor chip.

### Fourth Embodiment

A power conversion apparatus relating to the present embodiment is described. In the description hereinafter, the same reference numerals as those described in the above embodiment will be assigned to the similar constituent elements in the diagrams, and detailed description thereof is appropriately omitted.

### <Configuration of Power Conversion Apparatus>

In the present embodiment, the semiconductor device relating to the first embodiment, the second embodiment, and the third embodiment is applied to a power conversion apparatus. The present technique is not limited to a particular power conversion apparatus, however, described hereinafter is a case of applying the present technique to a three-phase inverter as a fourth embodiment.

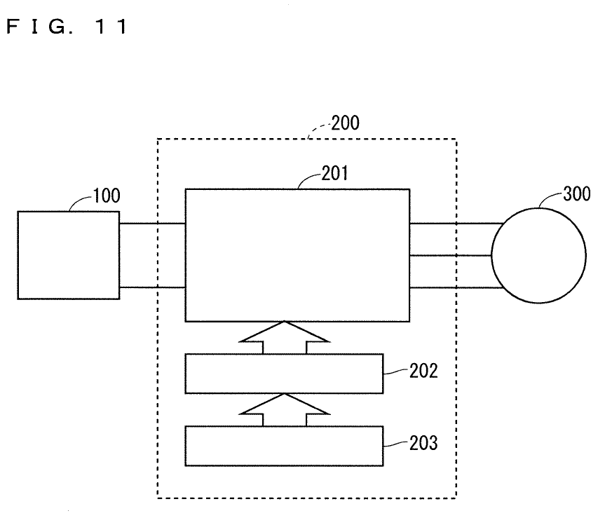

FIG. 11 is a block diagram illustrating a configuration of a power conversion system to which a power conversion apparatus according to the present embodiment is applied.

The power conversion system exemplified in FIG. 11 includes a power source 100, a power conversion apparatus 200, and a load 300. The power source 100 is a direct current power source, and supplies direct current power to the power conversion apparatus 200. The power source 100 can be made up of various components, thus can be made up of a direct current system, a solar battery, or a storage battery, for example, and may also be made up of a rectification circuit connected to an alternating current system or an AC/DC converter. The power source 100 may also be made up of a DC/DC converter converting a direct current power being output from a direct current system into predetermined power.

The power conversion apparatus 200 is a three-phase inverter connected between the power source 100 and the load 300, converts direct current power supplied from the power source 100 into alternating current power, and supplies the alternating current power to the load 300. As exemplified in FIG. 11, the power conversion apparatus 200 includes a main conversion circuit 201 converting direct current power into alternating current power and outputs the alternating current power, a drive circuit 202 outputting a drive signal driving each switching element of the main conversion circuit 201, and a control circuit 203 outputting a control signal controlling the drive circuit 202 to the drive circuit 202.

The load 300 is a three-phase electrical motor driven by the alternating current power supplied from the power conversion apparatus 200. The load 300 is not for a specific purpose of usage, but is an electrical motor mounted on various types of electrical apparatuses, thus is used as an electrical motor for a hybrid automobile, an electrical automobile, a railroad vehicle, an elevator, or an air-conditioning machine, for example.

Details of the power conversion apparatus 200 are described hereinafter. The main conversion circuit 201 includes a switching element and a reflux diode (not shown herein), and when the switching element is switched, the main conversion circuit 201 converts the direct current power supplied from the power source 100 into the alternating current power, and supplies the alternating current power to the load 300. There are various. specific circuit configurations of the main conversion circuit 201. The main conversion circuit 201 according to the present embodiment is a three-phase full-bridge circuit with two levels, and can be made up of six switching elements and six reflux diodes antiparallel to the switching elements, respectively. The semiconductor device according to any of the first embodiment, the second embodiment, and the third embodiment is applied to each switching element of the main conversion circuit 201. The six switching elements are connected two by two in series to constitute upper and lower arms, and each pair of the upper and lower arms constitutes each phase (U phase, V phase, and W phase) of a full-bridge circuit. Then, output terminals of each pair of the upper and lower arms, that is to say, three output terminals of the main conversion circuit 201 are connected to the load 300.

The drive circuit 202 generates the drive signal driving the switching element of the main conversion circuit 201, and supplies the drive signal to a control electrode of the switching element of the main conversion circuit 201. Specifically, the drive circuit 202 outputs a drive signal for making the switching element enter an ON state and a drive signal for making the switching element enter an OFF state to a control electrode of each switching element in accordance with a control signal from the control circuit 203 describe hereinafter. When the switching element is kept in the on state, the drive signal is a voltage signal (ON signal) equal to or larger than a threshold voltage of the switching element, and when the switching element is kept in the OFF state, the drive signal is a voltage signal (OFF signal) equal to or smaller than the threshold voltage of the switching element.

The control circuit 203 controls the switching element of the main conversion circuit 201 so that desired electrical power is supplied to the load 300. Specifically, the control circuit 203 calculates a time (ON time) at which each switching element of the main conversion circuit 201 should enter the ON state based on the electrical power to be supplied to the load 300. For example, the control circuit 203 can control the main conversion circuit 201 by PWM control modulating the ON time of the switching element in accordance with the voltage to be output. Then, the control circuit 203 outputs to a control command (control signal) to the drive circuit 202 so that the ON signal is output to the switching element which should enter the ON state and the OFF signal is output to the switching element which should enter the OFF state at each point of time. The drive circuit 202 outputs the ON signal or the OFF signal as the drive signal to the control electrode of each switching element in accordance with the control signal.

In the power conversion apparatus 200 relating to the present embodiment, the semiconductor device relating to the first embodiment, the second embodiment, and the third embodiment is applied as the switching element of the main conversion circuit 201, thus a low loss power conversion apparatus 200 with increased reliability of high-speed switching can be achieved.

Described in the present embodiment is the example of applying the present technique to the three-phase inverter with two levels. However, the present technique is not limited thereto, but can be applied to various power conversion apparatuses. The power conversion apparatus 200 with two levels is described in the present embodiment, however, a power conversion apparatus with three levels or multiple levels is also applicable, and the present technique may be applied to a single-phase inverter when the electrical power is supplied to a single-phase load. When the electrical power is supplied to a direct current load, for example, the present technique can also be applied to a DC/DC converter or an AC/DC converter.

The power conversion apparatus applying the present technique can be used not only in the case where the above load is the electrical motor but can be used as a power source apparatus of an electrical discharge machine, a laser beam machine, an induction heat cooking machine, or a wireless charging system, and further can also be used as a power conditioner of a solar power system or an electricity storage system, for example.

### <Effects Caused by Embodiments Described Above>

Examples of effects caused by the above embodiments are described hereinafter. It should be noted that, in the following description, the effects are described based on the specific configurations illustrated in the above described embodiments, however, other specific configurations may be applied in place of the configurations exemplified in the specification of the present application, within the scope of producing the similar effects. That is to say, in the description hereinafter, only one of the associated specific configurations is described as a representative in some cases, however, the specific configuration described as the representative may be replaced with the other associated specific configuration.

Also, the replacement may be implemented with a plurality of embodiments. That is to say, each of the configurations exemplified in the different embodiments may be combined with one another to produce the similar effects.

According to the embodiments described above, the semiconductor device includes the drift layer 20 of the first conductivity type (n-type); the plurality of well regions 30 (or the well region 30C and the well region 30D) of the second conductivity type (p-type), the n-type source region 40 (or the source region 40 and the source region 40D), the n-type first separation region, the n-type second separation region, the gate insulating film 50, the gate electrode 60, the Schottky electrode 71, the ohmic electrode 70, and the source electrode 80. Herein, the first separation region corresponds to at least one of the separation region 21, the separation region 21A, the separation region 21B, the separation region 21C, and the separation region 21D, for example. The second separation region corresponds to at least one of the separation region 22, the separation region 22C, and the separation region 22D, for example. The drift layer 20 is provided to the upper surface of the n-type semiconductor substrate 10. The well region 30 is provided separately from each other to the surface layer of the drift layer 20. The source region 40 is provided to the surface layer of the well region 30. The separation region 21 is the region between the plurality of well regions in the surface layer of the drift layer 20. The separation region 22 is the region between the plurality of well regions in the surface layer of the drift layer 20, and is the region different from the separation region 21. The gate insulating film 50 is provided to have contact with the well region 30 sandwiched between the source region 40 and the drift layer 20. The gate electrode 60 is provided to have contact with the gate insulating film 50. The Schottky electrode 71 is provided to the upper surface of the separation region 21 to have Schottky junction with the separation region 21. The ohmic electrode 70 is provided to the upper surface of the source region 40. The source electrode 80 is provided to have contact with the Schottky electrode 71 and the ohmic electrode 70. Then, the separation region 21 extends in the first direction and the second direction different from the first direction in a plan view. Herein, the first direction corresponds to the direction X, for example. The second direction corresponds to the direction Y, for example. The separation region 21 includes at least one first folding region folded back in the direction Y. Herein, the first folding region corresponds to at least one of the folding region 221, the folding region 221A, the folding region 221B, the folding region 221C, and the folding region 221D, for example. The separation region 22 extends in at least the direction X in a plan view. The width of the separation region 22 in the direction Y is equal to or larger than that of the separation region 21 in the direction X or the direction Y.

According to such a configuration, the folding region 221 is provided to the separation region 21, thus the amount of electrons flowing via the SBD can be increased without increasing the n-type concentration and the width of the separation region 21, and the maximum unipolar current density can be increased. In the meanwhile, the width of the separation region 21 is smaller than that of the separation region 22, thus the electrical field on the PN joint part formed by the separation region 21 and the well region 30 can be reduced. Thus, the maximum unipolar current density can be increased while the electrical field on the body diode in the OFF state of the transistor is reduced.

Even in the case where the other configurations other than the configurations exemplified in the specification of the present application is appropriately added to the configuration described above, that is to say, the other configurations other than the configurations in the specification of the present application, which are not referred to as configurations described above are appropriately added, the similar effects can be produced.

According to the embodiment described above, the plurality of folding regions 221 of the separation region 21 are provided. According to such a configuration, the folding region 221 is repetitively provided, thus the separation region 21 can have the meandering shape. Thus, the amount of electrons flowing via the SBD can be increased without increasing the n-type concentration and the width of the separation region 21, and the maximum unipolar current density can be increased.

According to the embodiment described above, the folding region 221 of the separation region 21 is provided at a constant distance interval. According to such a configuration, the cycle (the interval of the distance) in meandering of the separation region 21 is constant, thus the maximum unipolar current density in the active region in the semiconductor chip becomes uniform, and performance of the element can be increased. Confirmed by various calculations are effects that the maximum unipolar current density is improved by the structure.

According to the embodiment described above, the separation region 21 has the zigzag shape in a plan view. According to such a configuration, the folding region 221 repetitively provided can make the separation region 21 have the zigzag shape. Thus, the amount of electrons flowing via the SBD can be increased without increasing the n-type concentration and the width of the separation region 21, and the maximum unipolar current density can be increased. The separation region 21 is meanderingly disposed to have the zigzag shape, thus the photoresist used in the Al ion implantation is also meanderingly formed. In this case, the photoresist falls more hardly than a case of forming the photoresist in straight, thus occurrence of pattern defect can be suppressed.

According to the embodiment described above, the separation region 22C extends in the direction Y in a plan view. The separation region 22C includes at least one second folding region folded back in the direction Y. Herein, the second folding region corresponds to the folding region 222C, for example. The folding region 221C and the folding region 222C are provided to correspond to each other, thus the separation region 21C and the separation region 22C extend in the direction X in parallel to each other. According to such a configuration, the separation region 21C and the separation region 22C extend in the direction X in parallel to each other, and the pitch of the cells in the direction Y in FIG. 8 can be reduced. Thus, the semiconductor chip can be downsized.

According to the embodiments described above, the direction X is perpendicular to the direction Y. The well region 30 (or the well region 30C) and the gate electrode 60 have the stripe shape extending in the direction X in a plan view. According to such a configuration, the meandering separation region 21 can be continuously disposed in the direction X, thus the SBD current density in the semiconductor chip can be uniformized more easily than a case where the separation region 21 is intermittently disposed in the direction X. According to such a configuration, the meandering shape extends in the directions perpendicular to each other, thus a layout can be easily performed.

According to the embodiment described above, the folding region 221B has the curved shape in a plan view. According to such a configuration, change of the width of the separation region 21B is reduced when the separation region 21B is bended. Thus, the electrical field concentration in the PN joint part formed by the separation region 21B and the well region 30 in the OFF state of the transistor is easily reduced.

According to the embodiments described above, the semiconductor device includes the trench passing through the well region 30 to reach the drift layer 20. Then, the gate insulating film 50 is formed to cover the lateral surface of the well region 30 sandwiched between the source region 40 and the drift layer 20 in the trench. The gate electrode 60 is formed to be surrounded by the gate insulating film 50 in the trench. According to such a configuration, the technique described in the embodiment described above can be applied to not only the planar gate type MOSFET but also the trench gate type MOSFET.

According to the embodiments described above, the power conversion apparatus includes the semiconductor device described above, and further includes the main conversion circuit 201 converting the electrical power which has been inputted and outputting the converted electrical power, the drive circuit 202 outputting the drive signal for driving the semiconductor device to the semiconductor device, and the control circuit 203 outputting the control signal for controlling the drive circuit 202 to the drive circuit 202. According to such a configuration, the semiconductor device described above is used, thus the maximum unipolar current density can be increased while the electrical field on the body diode in the OFF state of the transistor is reduced.

### <Modification Example of Embodiments Described Above>

In the embodiments described above, material properties, materials, dimensions, shapes, relative arrangement relations, conditions for implementation, and so forth for the respective constituent elements may be described, however, these represent one example in all aspects, and are not limited to the description in the specification of the present application.

Accordingly, it is understood that numerous other modification examples and equivalents which are not exemplified can be devised without departing from the scope of the technique disclosed in the specification of the present application. For example, the following cases where at least one of the constituent elements is to be modified, added, or omitted, further, at least one of the constituent elements of at least one of the embodiments is extracted and then combined with constituent elements of the other embodiment, are involved.

Further, in at least one of the embodiments described above, when names of materials are stated unless otherwise specified, an alloy of the material and other additives, and so forth are included, so far as consistent with the embodiments.

The “one” constituent element described in the embodiments described above may be “one or more” constituent elements so far as consistent with the embodiments.

Further, individual constituent elements are conceptual units. Thus, within the range of the technique disclosed in the specification of the present application, one constituent element may include multiple structures, one constituent element may correspond to part of some structure, and multiple constituent elements may be included in one structure.

Each constituent element includes a structure having a different configuration or a different shape as long as the structure of the different configuration or the different shape achieves the same function in each constituent element in the embodiments described above.

What has been described in the specification of the present application is referred for all purposes regarding the present technique. It is thus not an admission that any of the descriptions provided herein are conventional techniques.

### EXPLANATION OF REFERENCE SIGNS

10 semiconductor substrate, 20 drift layer, 21 separation region, 21A separation region, 21B separation region, 21C separation region, 21D separation region, 22 separation region, 22C separation region, 22D separation region, 30 well region, 30C well region, 30D well region, 32 protection region, 33 protection region, 34 separation region, 40 source region, 40C source region, 40D source region, 50 gate insulating film, 50A gate insulating film, 60 gate electrode, 60A gate electrode, 70 ohmic electrode, 71 Schottky electrode, 71A Schottky electrode, 80 source electrode, 200 power conversion apparatus, 201 main conversion circuit, 202 drive circuit, 203 control circuit, 221 folding region, 221A folding region, 221B folding region, 221C folding region, 221D folding region, 222C folding region, 302 gate trench, 303 Schottky trench, 304 folding region.

1. A semiconductor device, comprising:
a drift layer of a first conductivity type provided to an upper surface of a semiconductor substrate of a first conductivity type;
a plurality of well regions of a second conductivity type provided separately from each other on a surface layer of the drift layer;
a source region of a first conductivity type provided to a surface layer of at least one of the well regions;
a first separation region of a first conductivity type as a region between the plurality of well regions on the surface layer of the drift layer;
a second separation region of a first conductivity type as a region, different from the first separation region, between the plurality of well regions on the surface layer of the drift layer;
a gate insulating film provided to have contact with at least one of the well regions sandwiched between the source region and the drift layer;
a gate electrode provided to have contact with the gate insulating film;
a Schottky electrode provided to an upper surface of the first separation region to have a Schottky junction with the first separation region;
an ohmic electrode provided to an upper surface of the source region; and
a source electrode provided to have contact with the Schottky electrode and the ohmic electrode, wherein
the first separation region extends in a first direction and a second direction as a direction different from the first direction in a plan view,
the first separation region includes at least one first folding region folded back in the second direction,
the second separation region extends in at least the first direction in a plan view, and
a width of the second separation region in the second direction is equal to or larger than a width of the first separation region in the first direction or the second direction.

2. The semiconductor device according to claim 1, wherein
the plurality of first folding regions of the first separation region are provided.

3. The semiconductor device according to claim 2, wherein
the first folding region of the first separation region is provided at a regular interval.

4. The semiconductor device according to claim 2, wherein
the first separation region has a zigzag shape in a plan view.

5. The semiconductor device according to claim 1, wherein
the second separation region extends in the second direction in a plan view,
the second separation region includes at least one second folding region folded back in the second direction, and
the first folding region and the second folding region are provided to correspond to each other, thus the first separation region and the second separation region extend in the first direction in parallel to each other.

6. A semiconductor device, comprising:
a drift layer of a first conductivity type provided to an upper surface of a semiconductor substrate of a first conductivity type;
a plurality of well regions of a second conductivity type provided separately from each other on a surface layer of the drift layer;
a source region of a first conductivity type provided to a surface layer of at least one of the well regions;
a first trench provided to reach inside the drift layer from an upper surface of at least one of the well regions;
a second trench provided to a position different from the first trench to reach inside the drift layer from an upper surface of at least one of the well regions;
a separation region sandwiched between the first trench and the second trench;
a gate insulating film covering a lateral surface of at least one of the well regions sandwiched between the source region and the drift layer in the second trench;
a gate electrode formed to be surrounded by the gate insulating film in the second trench;
a Schottky electrode having a Schottky junction with the separation region in the first trench;
an ohmic electrode provided to an upper surface of the source region; and
a source electrode provided to have contact with the Schottky electrode and the ohmic electrode, wherein
the first trench extends in a first direction and a second direction as a direction different from the first direction in a plan view,
the first trench includes at least one first folding region folded back in the second direction,
the second trench extends in at least the first direction in a plan view, and
a depth of the second trench from an upper surface of at least one of the well regions is equal to or larger than a depth of the first trench from the upper surface of at least one of the well regions.

7. The semiconductor device according to claim 6, wherein
the plurality of first folding regions of the first trench are provided.

8. The semiconductor device according to claim 7, wherein
the first folding region of the first trench is provided at a regular interval.

9. The semiconductor device according to claim 7, wherein
the first trench has a zigzag shape in a plan view.

10. The semiconductor device according to claim 6, wherein
the second trench extends in the second direction in a plan view,
the second trench includes at least one second folding region folded back in the second direction, and
the first folding region and the second folding region are provided to correspond to each other, thus the first trench and the second trench extend in the first direction in parallel to each other.

11. The semiconductor device according to claim 1, wherein
the first direction is perpendicular to the second direction, and
the gate electrode and at least one of the well regions have a stripe shape extending in the first direction in a plan view.

12. The semiconductor device according to claim 1, wherein
the first folding region has a curved shape in a plan view.

13. A power conversion apparatus, comprising:
a main conversion circuit including the semiconductor device according to claim 1, converting electrical power which has been input, and outputting the electrical power;
a drive circuit outputting a drive signal for driving the semiconductor device to the semiconductor device; and
a control circuit outputting a control signal for controlling the drive circuit to the drive circuit.

14. The semiconductor device according to claim 6, wherein
the first direction is perpendicular to the second direction, and
the gate electrode and at least one of the well regions have a stripe shape extending in the first direction in a plan view.

15. The semiconductor device according to claim 6, wherein
the first folding region has a curved shape in a plan view.

16. A power conversion apparatus, comprising:
a main conversion circuit including the semiconductor device according to claim 6, converting electrical power which has been input, and outputting the electrical power;
a drive circuit outputting a drive signal for driving the semiconductor device to the semiconductor device; and
a control circuit outputting a control signal for controlling the drive circuit to the drive circuit.
